(19) United States
(12) Patent Application Publication
(10) Pub. No.: US 2023/0200149 A1
(43) Pub. Date: Jun. 22, 2023

(54) DISPLAY DEVICE

(71) Applicant: LG DISPLAY CO., LTD., Seoul (KR)

(72) Inventors: SungJi YOON, Gyeonggi-do (KR); HwaYong SHIN, Gyeonggi-do (KR)

(73) Assignee: LG DISPLAY CO., LTD., SEOUL (KR)

(21) Appl. No.: 17/954,935

(22) Filed: Sep. 28, 2022

(30) Foreign Application Priority Data
Dec. 21, 2021 (KR) 10-2021-0183427

(51) Int. Cl. H01L 27/32; H01L 51/52

(52) U.S. Cl. CPC H01L 27/3258; H01L 51/52

(57) ABSTRACT

A display device includes a substrate provided with a plurality of transmissive areas, a plurality of light emitting elements disposed between the plurality of transmissive areas and comprised of a first electrode, a light emitting layer and a second electrode, and a first light path changing layer disposed between the plurality of transmissive areas, changing a path of light directed from the light emitting layer toward the substrate, thereby reducing interference light due to a light emitting element when an optical sensor operates.

### CROSS-REFERENCE TO RELATED APPLICATION

This application claims the priority of Korean Patent Application No. 10-2021-0183427 filed on Dec. 21, 2021, which is hereby incorporated by reference in its entirety.

### BACKGROUND

### Field of the Disclosure

The present disclosure relates to a display device with an optical sensor.

### Description of the Background

A display device includes various display elements such as a liquid crystal display element or an organic light emitting element in a display area. A display device has been devised to apply various applications by embedding a camera therein to link a display area to the camera.

In the display device, the camera may be disposed below a display panel. In this way, the display device embedded with a camera may not display an image in an area overlapping with the camera, and in this case, the image displayed on the display device may be disconnected and recognized by a user.

Meanwhile, when an image is displayed in the area overlapping with the camera, light emitted from a light emitting element may be incident on the camera of the display device. As a result, the display device may have poor camera performance due to interference light caused by the light emitting element.

### SUMMARY

Accordingly, the present disclosure is to provide a display device that can display an image even in an area overlapping with an optical sensor.

The present disclosure is also to provide a display device that reduce interference light due to a light emitting element when an optical sensor operates.

In addition to the mentioned above, additional advantages and features of the present disclosure will be clearly understood by those skilled in the art from the following description of the present disclosure.

In accordance with an aspect of the present disclosure, a display device includes a substrate provided with a plurality of transmissive areas, a plurality of light emitting elements disposed between the plurality of transmissive areas and comprised of a first electrode, a light emitting layer and a second electrode, and a first light path changing layer disposed between the plurality of transmissive areas, changing a path of light directed from the light emitting layer toward the substrate.

In accordance with another aspect of the present disclosure, a display device includes a display panel provided with a plurality of subpixels to display an image, and an optical sensor disposed below the display panel, wherein the display panel includes a substrate provided with a first display area and a second display area overlapping with the optical sensor, a plurality of first subpixels disposed in the first display area, a plurality of second subpixels disposed in the second display area, and a first light path changing layer disposed to overlap each of the second subpixels, changing a path of light directed from the second subpixels toward the substrate.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description taken in conjunction with the accompanying drawings, in which:

FIG. 1 is a schematic plan view illustrating a display device according to one aspect of the present disclosure;

FIG. 2 is a schematic exploded view illustrating a display device according to one aspect of the present disclosure;

FIG. 3 is a schematic plan view illustrating subpixels disposed in a display panel according to one aspect of the present disclosure;

FIG. 4 is a view illustrating an operation relation between an optical sensor and a pixel;

FIG. 5 is a cross-sectional view as taken along line of I-I′ of FIG. 3;

FIG. 6 is a cross-sectional view as taken along line of II-II′ of FIG. 3;

FIG. 7 is a cross-sectional view as taken along line of II-II′ of FIG. 3;

FIG. 8 is a view illustrating an operation relation between an optical sensor and a second subpixel;

FIG. 9 is a view illustrating that interference light due to a second subpixel occurs when an optical sensor operates;

FIG. 10 is a view illustrating that incident light of interference light due to a second subpixel is changed by a first light path changing layer; and

FIG. 11 is a graph illustrating intensity of light in a comparative example and an aspect.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example. Thus, the present disclosure is not limited to the illustrated details. Unless otherwise described, like reference numerals refer to like elements throughout. In the following description, when the detailed description of the relevant known function or configuration is determined to unnecessarily obscure an important point of the present disclosure, the detailed description of such known function or configuration may be omitted. In a case where terms “comprise,” “have,” and “include” described in the present specification are used, another part may be added unless a more limiting term, such as “only,” is used. The terms of a singular form may include plural forms unless referred to the contrary.

In construing an element, the element is construed as including an error or tolerance range even where no explicit description of such an error or tolerance range.

In describing a position relationship, when a position relation between two parts is described as, for example, “on,” “over,” “under,” or “next,” one or more other parts may be disposed between the two parts unless a more limiting term, such as “just” or “direct(ly),” is used.

It will be understood that, although the terms like “first,” “second,” etc., may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing elements of the present disclosure, the terms like “first,” “second,” “A,” “B,” “(a),” and “(b)” may be used. These terms are merely for differentiating one element from another element, and the essence, sequence, order, or number of a corresponding element should not be limited by the terms. Also, when an element or layer is described as being “connected,” “coupled,” or “adhered” to another element or layer, the element or layer can not only be directly connected or adhered to that other element or layer, but also be indirectly connected or adhered to the other element or layer with one or more intervening elements or layers “disposed” between the elements or layers, unless otherwise specified.

Features of various aspects of the present disclosure may be partially or overall coupled to or combined with each other, and may be variously inter-operated with each other and driven technically as those skilled in the art can sufficiently understand. Aspects of the present disclosure may be carried out independently from each other, or may be carried out together in a co-dependent relationship.

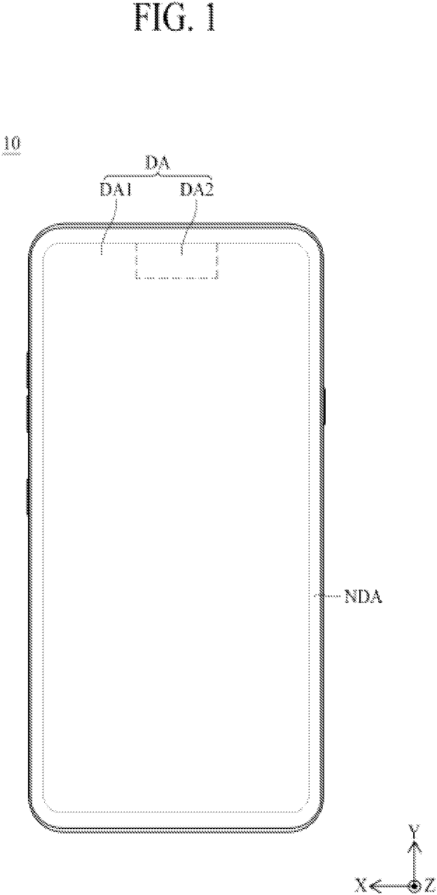

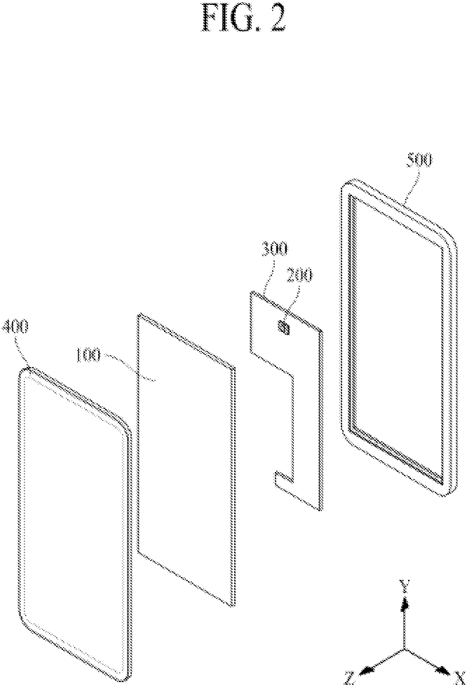

FIG. 1 is a schematic plan view illustrating a display device according to one aspect of the present disclosure, and FIG. 2 is a schematic exploded view illustrating a display device according to one aspect of the present disclosure.

Referring to FIGS. 1 and 2, a display device 10 according to one aspect of the present disclosure may include a display panel 100, an optical sensor 200, a circuit board 300, a cover window 400 and a frame 500.

The display panel 100 may be categorized into a display area DA in which pixels are formed to display an image and a non-display area NDA in which an image is not displayed.

The non-display area NDA may be disposed to surround the display area DA. The non-display area NDA may include a driver for supplying various signals to a plurality of signal lines in the display area DA and a link portion for connecting the driver with the plurality of signal lines. The driver may include a gate driver for supplying a gate signal to a gate line and a data driver for supplying a data signal to a data line.

Although a description has been described based on that the transparent display device according to one aspect of the present disclosure is embodied as an organic light emitting display device, the transparent display device may be embodied as a liquid crystal display device, a plasma display panel (PDP), a Quantum dot Light Emitting Display (QLED) or an Electrophoresis display device.

The optical sensor 200 may be disposed over a rear surface of the display panel 100. The optical sensor 200 may be provided to at least partially overlap the display area DA of the display panel 100, particularly a second display area DA2. The optical sensor 200 may mean all elements that measure external light input through the display panel 100 to use the measured external light. For example, the optical sensor 200 may be a camera, but is not limited thereto. The optical sensor 200 may be an illuminance sensor, a fingerprint sensor or the like.

The circuit board 300 may be disposed over the rear surface of the display panel 100. The circuit board 300 may be a printed circuit board (PCB) or a flexible printed circuit board (FPCB).

The cover window 400 may be disposed over a front surface of the display panel 100. The cover window 400 may protect the display panel 100 from external impact by covering the front surface of the display panel 100.

The cover window 400 may be made of a transparent plastic material, a glass material, or a reinforced glass material. As an example, the cover window 400 may have any one or a stacked structure of sapphire glass and a gorilla glass. As another example, the cover window 400 may include any one of polyethyleneterephthalate (PET), polycarbonate (PC), polyethersulfone (PES), polyethylenapthanate (PEN) and polynorbornene (PNB). The cover window 400 may be made of reinforced glass in consideration of scratch and transparency.

The frame 500 may accommodate the display panel 100 and support the cover window 400. The frame 500 may include an accommodating portion that may accommodate the optical sensor 200 and the circuit board 300. The frame 500 allows the display panel 100, the optical sensor 200 and the circuit board 300 to be fixed to the display device 10. The frame 500 may serve to protect the display panel 100, the optical sensor 200 and the circuit board 300 from impact. The frame 500 may be a middle frame or a housing, but is not limited thereto.

Hereinafter, the subpixels disposed in a first display area DA1 and the second display area DA2 of the display panel 100 will be described in detail.

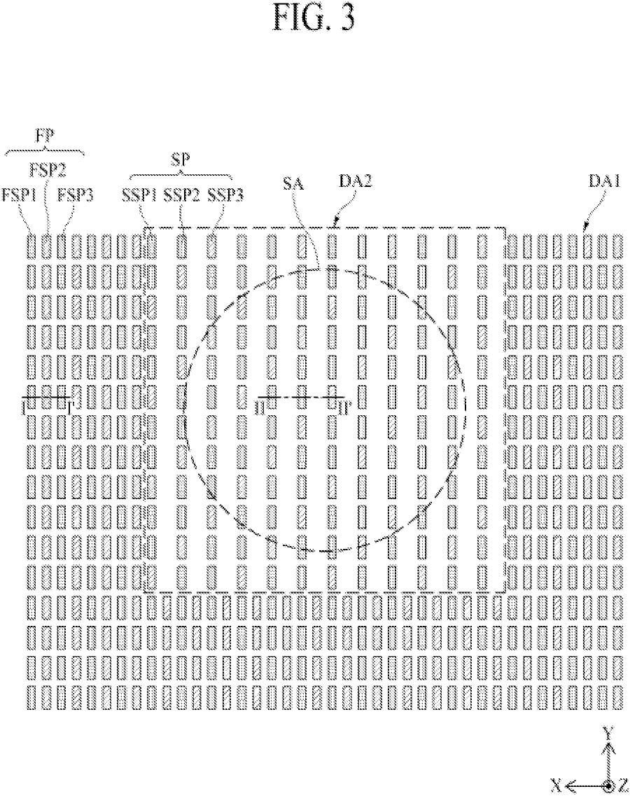

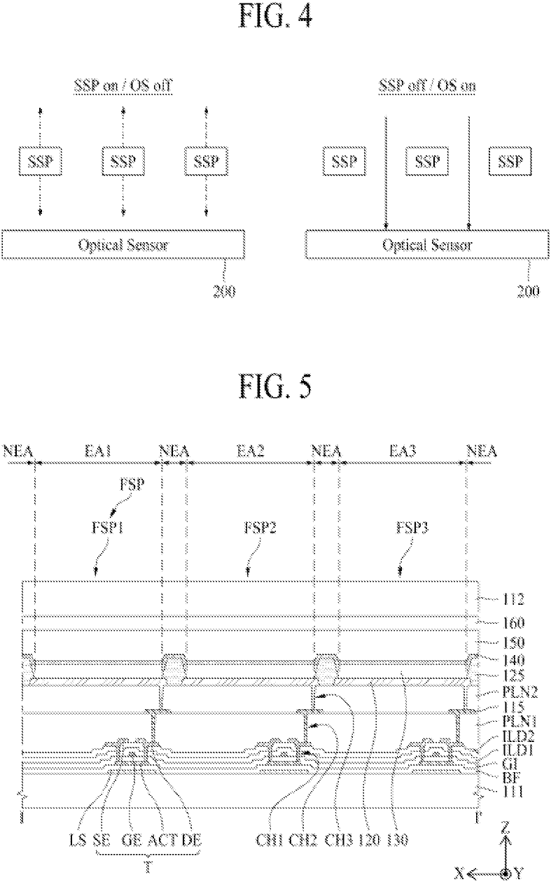

FIG. 3 is a schematic plan view illustrating subpixels disposed in a display panel according to one aspect of the present disclosure, and FIG. 4 is a view illustrating an operation relation between an optical sensor and a pixel.

Referring to FIGS. 3 and 4, the display panel 100 includes a first display area DA1 and a second display area DA2. The first display area DA1 is an area in which a plurality of first pixels FP are disposed and emit light to display an image regardless of whether the optical sensor 200 is operated. Each of the plurality of first pixels FP may include a plurality of first subpixels FSP.

The second display area DA2 is disposed to at least partially overlap an area SA in which the optical sensor 200 is disposed. A plurality of second pixels SP may be disposed in the second display area DA2, and whether an image is displayed may be determined depending on whether the optical sensor 200 is operated.

In detail, when the operation of the optical sensor 200 is turned off, a plurality of second subpixels SSP may be turned on as shown in FIG. 4. Therefore, the plurality of second subpixels SSP may emit light to display an image in the second display area DA2.

On the other hand, when the optical sensor 200 is turned on, the plurality of second subpixels SSP may be turned off. Therefore, an image may not be displayed on the second display area DA2, and external light may be input to the optical sensor 200.

The optical sensor 200 may measure external light while periodically repeating an on-off operation. In addition, the plurality of second subpixels SSP may display an image on the second display area DA2 while periodically repeating the on-off operation. The display panel 110 may turn on-off the optical sensor 200 and the plurality of second subpixels SSP at a period at which a user cannot recognize. Therefore, the user may recognize that the image is displayed on the second display area DA2 as well as the first display area DA1 and at the same time the optical sensor 200 operates.

A size and position of the second display area DA2 may be determined in consideration of the optical sensor 200. The second display area DA2 may be provided at a position corresponding to the optical sensor 200. The second display area DA2 may be provided at a size that includes an area SA in which the optical sensor 200 is disposed.

Hereinafter, the first display area DA1 will be described in more detail with reference to FIG. 5.

FIG. 5 is a cross-sectional view as taken along line of I-I′ of FIG. 3.

Referring to FIGS. 3 and 5, the first display area DA1 may be a non-transmissive area NTA. In this case, the non-transmissive area may be an area that does not transmit most of light incident from the outside. For example, the non-transmissive area may be an area having light transmittance of β%, for example, 50%.

The first display area DA1 may be provided with a plurality of first pixels FP. The first pixels FP emit predetermined light to display an image. A light emission area EA may correspond to an area that emits light in the first pixel FP.

Each of the plurality of first pixels FP may include a plurality of first subpixels FSP. The plurality of first subpixels FSP may include a first color subpixel FSP1, a second color subpixel FSP2 and a third color subpixel FSP3. The first color subpixel FSP1 may emit red light, the second color subpixel FSP2 may emit green light, and the third color subpixel FSP3 may emit blue light, but the present disclosure is not limited thereto. Each of the first pixels FP may further include a fourth color subpixel emitting white light. The arrangement order of the first subpixels FSP is not limited to that shown in FIG. 3, but may be changed in various ways.

A circuit element, which includes a capacitor, a thin film transistor and the like, and a light emitting element may be provided in each of the first color subpixel FSP1, the second color subpixel FSP2 and the third color subpixel FSP3. The thin film transistor may include a switching transistor, a sensing transistor, and a driving transistor T.

The switching transistor may be switched in accordance with the scan signal supplied to the scan line to charge the data voltage supplied from the data line in the capacitor. The sensing transistor may sense a threshold voltage deviation of the driving transistor T, which may cause deterioration of image quality.

The driving transistor T is switched in accordance with the data voltage charged in the capacitor to generate a data current from a power source supplied from a pixel power line to supply the data current to a first electrode 120 of the subpixels FSP1, FSP2 and FSP3. The driving transistor T may include an active layer ACT, a gate electrode GE, a source electrode SE and a drain electrode DE.

In detail, a light shielding layer LS may be provided over the first substrate 111. The light shielding layer LS serves to shield external light incident on the active layer ACT in the area where the driving transistor T is provided. The light shielding layer LS may be formed of a single layer or multiple layers made of any one of molybdenum (Mo), aluminum (Al), chromium (Cr), gold (Au), titanium (Ti), nickel (Ni), neodymium (Nd) and copper (Cu) or their alloy.

A buffer layer BF may be provided over the light shielding layer LS. The buffer layer BF is for protecting the transistors T from water permeated through the first substrate 111 vulnerable to moisture permeation, and may be formed of an inorganic layer, for example, a silicon oxide layer (SiOx), a silicon nitride layer (SiNx), or multiple layers of SiOx and SiNx.

The active layer ACT may be provided over the buffer layer BF. The active layer ACT may be formed of a silicon-based semiconductor material or an oxide-based semiconductor material.

A gate insulating layer GI may be provided over the active layer ACT. The gate insulating layer GI may be formed of an inorganic layer, for example, a silicon oxide layer (SiOx), a silicon nitride layer (SiNx), or multiple layers of SiOx and SiNx.

A gate electrode GE may be provided over the gate insulating layer GI. The gate electrode GE may be formed of a single layer or multiple layers including at least one of molybdenum (Mo), aluminum (Al), chromium (Cr), gold (Au), titanium (Ti), nickel (Ni), neodymium (Nd) and copper (Cu), or their alloy.

A first interlayer dielectric layer ILD1 and a second interlayer dielectric layer ILD2 may be provided over the gate electrode GE. The first interlayer dielectric layer ILD1 and a second interlayer dielectric layer ILD2 may be formed of an inorganic layer, for example, a silicon oxide layer (SiOx), a silicon nitride layer (SiNx), or multiple layers of SiOx and SiNx.

The source electrode SE and the drain electrode DE may be provided over the second interlayer dielectric layer ILD2. One of the source electrode SE and the drain electrode DE may be connected to the active layer ACT through a first contact hole CH1 that passes through the gate insulating layer GI, the first interlayer dielectric layer ILD1 and a second interlayer dielectric layer ILD2. The source electrode SE and the drain electrode DE may be formed of a single layer or multiple layers including at least one of molybdenum (Mo), aluminum (Al), chromium (Cr), gold (Au), titanium (Ti), nickel (Ni), neodymium (Nd) and copper (Cu), or their alloy.

A first planarization layer PLN1 for planarizing a step difference due to the driving transistor T may be provided over the source electrode SE and the drain electrode DE. The first planarization layer PLN1 may be formed of an organic layer such as an acrylic resin, an epoxy resin, a phenolic resin, a polyamide resin and a polyimide resin.

An auxiliary electrode 115 may be provided over the first planarization layer PLN1. The auxiliary electrode 115 may be connected to one of the source electrode SE and the drain electrode DE of the driving transistor T through a second contact hole CH2 that passes through the first planarization layer PLN1. The auxiliary electrode 115 may be formed of a single layer or multiple layers including at least one of molybdenum (Mo), aluminum (Al), chromium (Cr), gold (Au), titanium (Ti), nickel (Ni), neodymium (Nd) and copper (Cu), or their alloy

A second planarization layer PLN2 may be provided over the auxiliary electrode 115. The second planarization layer PLN2 may be formed of an organic layer such as an acrylic resin, an epoxy resin, a phenolic resin, a polyamide resin and a polyimide resin.

A light emitting element, which includes a first electrode 120, an organic light emitting layer 130 and a second electrode 140 and a bank 125 may be provided over the second planarization layer PLN2.

The first electrode 120 may be provided over the second planarization layer PLN2 for each of the subpixels FSP1, FSP2 and FSP3. The first electrode 120 may be connected to the driving transistor T. In detail, the first electrode 120 may be connected to the auxiliary electrode 115 through a third contact hole CH3 that passes through the second planarization layer PLN2. Since the auxiliary electrode 115 may be connected to the source electrode SE or the drain electrode DE of the driving transistor T through the second contact hole CH2, the first electrode 120 may be electrically connected to the driving transistor T.

The first electrode 120 may be formed of a metal material having high reflectance, such as a stacked structure (Ti/Al/Ti) of aluminum and titanium, a stacked structure (ITO/Al/ITO) of aluminum and ITO, an Ag alloy, a stacked structure (ITO/Ag alloy/ITO) of Ag alloy and ITO, a MoTi alloy, and a stacked structure (ITO/MoTi alloy/ITO) of MoTi alloy and ITO. The Ag alloy may be an alloy of silver (Ag), palladium (Pd), copper (Cu), etc. The MoTi alloy may be an alloy of molybdenum (Mo) and titanium (Ti). The first electrode 120 may be an anode electrode.

The bank 125 may be provided over the second planarization layer PLN2. The bank 125 may be formed to at least partially cover an edge of the first electrode 120 and expose a portion of the first electrode 120. Therefore, the bank 125 may prevent a problem in which light emitting efficiency is deteriorated due to concentration of a current on an end of the first electrode 120.

The bank 125 may define light emission areas EA1, EA2 and EA3 of the subpixels FSP1, FSP2 and FSP3. The light emission areas EA1, EA2 and EA3 of each of the subpixels FSP1, FSP2 and FSP3 represent an area in which the first electrode 120, the organic light emitting layer 130 and the second electrode 140 are sequentially stacked and holes from the first electrode 120 and electrons from the second electrode 140 are combined with each other in the organic light emitting layer 130 to emit light. In this case, the area in which the bank 125 is provided may become the non-light emission area NEAbecause light is not emitted therefrom, and the area in which the bank 125 is not provided and the first electrode 120 is exposed may become the light emission area EA.

The bank 125 may be include at least one of an organic layer such as an acrylic resin, an epoxy resin, a phenolic resin, a polyamide resin, and a polyimide resin.

An organic light emitting layer 130 may be provided over the first electrode 120. The organic light emitting layer 130 may include a hole transporting layer, a light emitting layer and an electron transporting layer. In this case, when a voltage is applied to the first electrode 120 and the second electrode 140, holes and electrons move to the light emitting layer through the hole transporting layer and the electron transporting layer, respectively and are combined with each other in the light emitting layer to emit light.

In one aspect, the organic light emitting layer 130 may be formed for each of the subpixels FSP1, FSP2 and FSP3. For example, a red light emitting layer for emitting red light may be provided in the first color subpixel FSP1, a green light emitting layer for emitting green light may be provided in the second color subpixel FSP2, and a blue light emitting layer for emitting blue light may be provided in the third color subpixel FSP3.

In another aspect, the organic light emitting layer 130 may be a common layer commonly provided in the subpixels FSP1, FSP2 and FSP3. In this case, light emitting layer may be a white light emitting layer for emitting white light.

The second electrode 140 may be provided over the organic light emitting layer 130 and the bank 125. The second electrode 140 may be provided in the non-transmissive area that includes a light emission area EA. The second electrode 140 may be a common layer that is commonly provided in the subpixels FSP1, FSP2 and FSP3 to apply the same voltage.

The second electrode 140 may be formed of a semi-transmissive conductive material such as magnesium (Mg), silver (Ag) or an alloy of magnesium (Mg) and silver (Ag). Therefore, the second electrode 140 may increase light emitting efficiency by a micro cavity. The second electrode 140 may be a cathode electrode.

An encapsulation layer 150 may be provided over light emitting element. The encapsulation layer 150 may be provided over the second electrode 140 to cover the second electrode 140. The encapsulation layer 150 serves to prevent oxygen or moisture from being permeated into the organic light emitting layer 130 and the second electrode 140. To this end, the encapsulation layer 150 may include at least one inorganic layer and at least one organic layer.

Meanwhile, although not shown in FIG. 5, a capping layer may be additionally provided between the second electrode 140 and the encapsulation layer 150.

The first substrate 111 and the second substrate 112, in which the encapsulation layer 150 is provide, may be bonded to each other by a separate adhesive layer 160. The adhesive layer 160 may be an optically clear resin layer (OCR) or an optically clear adhesive film (OCA).

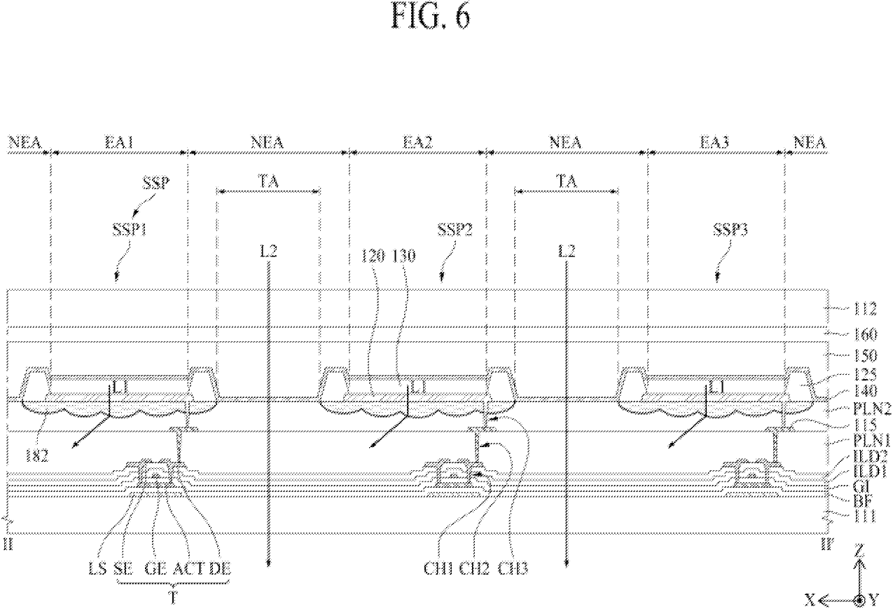

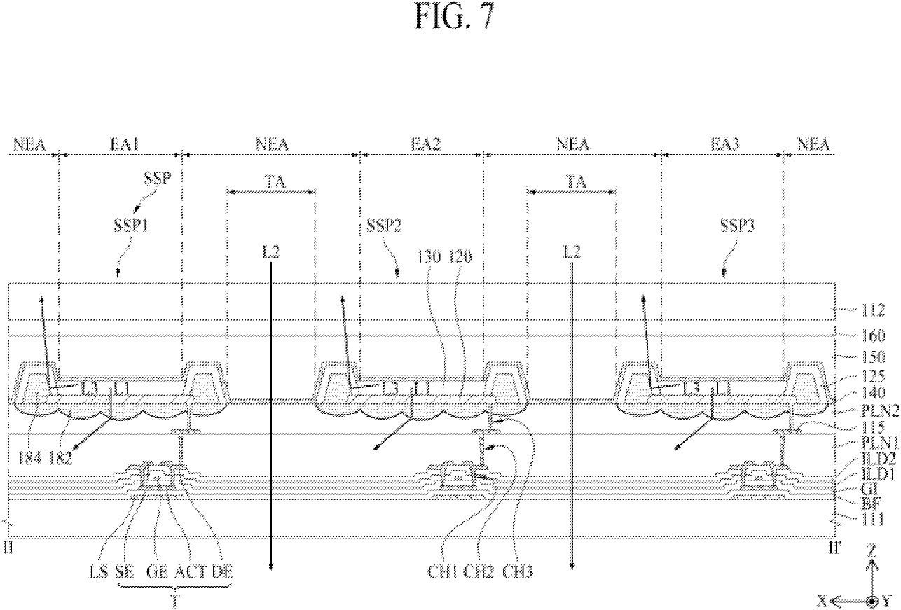

Hereinafter, the second display area DA2 will be described in more detail with reference to FIGS. 6 and 7.

FIG. 6 is a cross-sectional view as taken along line of II-II of FIG. 3.

Referring to FIG. 6, the second display area DA2 may include a transmissive area TA and a non-transmissive area NTA. In this case, the transmissive area TA may be an area that transmit most of light incident from the outside, and the non-transmissive area may be an area that does not transmit most of light incident from the outside. For example, the transmissive area TA may be an area having light transmittance of α%, for example, 90%. The non-transmissive area may be an area having light transmittance of β%, for example, 50%. In this case, αis a value greater than β. The optical sensor 200 disposed on the rear surface of the display panel 100 may receive the external light through the transmission areas TA.

The second display area DA2 may be provided with a plurality of second pixels SP. The second pixels SP may be provided in the non-transmissive area disposed between the transmissive areas TA and may emit predetermined light to display an image. A light emission area EA may correspond to an area that emits light in the second pixel SP.

Each of the plurality of second pixels SP may include a plurality of second subpixels SSP. The plurality of second subpixels SSP may include a first color subpixel SSP1, a second color subpixel SSP2 and a third color subpixel SSP3. The first color subpixel SSP1 may emit red light, the second color subpixel SSP2 may emit green light, and the third color subpixel SSP3 may emit blue light, but the present disclosure is not limited thereto. Each of the second pixels SP may further include a fourth color subpixel emitting white light. The arrangement order of the second subpixels SSP is not limited to that shown in FIG. 3, but may be changed in various ways.

A circuit element, which includes a capacitor, a thin film transistor and the like, and a light emitting element may be provided in each of the first color subpixel SSP1, the second color subpixel SSP2 and the third color subpixel SSP3. The thin film transistor may include a switching transistor, a sensing transistor, and a driving transistor T.

Since a transistor T of the second subpixel SSP includes elements substantially the same as those of a transistor T of the first subpixel FSP, a detailed description thereof will be omitted. In addition, since the light emitting element of the second subpixel SSP is substantially the same as that of the first subpixel FSP, its detailed description will be omitted. Hereinafter, the description will be based on a difference from the first subpixel.

The light emitting element of each of the second subpixels SSP may be disposed between the plurality of transmissive areas TA. In detail, a first electrode 120 and an organic light emitting layer 130 of the light emitting element may be patterned for each of the second subpixels SSP1, SSP2 and SSP3 between the plurality of transmissive areas TA. That is, the first electrode 120 and the organic light emitting layer 130 of the light emitting element may not be provided in the plurality of transmissive areas TA. The display panel 100 according to one aspect of the present disclosure may prevent light from being lost by the first electrode 120 and the organic light emitting layer 130 in the transmissive areas TA, thereby improving light transmittance of the transmissive area TA.

Meanwhile, a second electrode 140 of the light emitting element may be also provided in the transmissive area TA as well as the non-transmissive area NTA. Since the second electrode 140 is made of a transparent metal material capable of transmitting light, light transmittance of the transmissive area TA may not be reduced even though the second electrode 140 is provided in the transmissive area TA, but the present disclosure is not limited thereto. The second electrode 140 may not be provided in the transmissive area TA.

The display panel 100 according to one aspect of the present disclosure includes a first light path changing layer 182.

The first light path changing layer 182 may be disposed to at least partially overlap each of the plurality of second subpixels SSP, and may change a path of light L1 from the second subpixels SSP toward a first substrate 111. In detail, the first light path changing layer 182 may be disposed between the plurality of transmissive areas TA. The first light path changing layer 182 may not be disposed in the plurality of transmissive areas TA. When the first light path changing layer 182 is disposed in the plurality of transmissive areas TA, external light L2 may be refracted while passing through the first light path changing layer 182. In this case, the optical sensor 200 disposed below the display panel 100 may receive light refracted by the first light path changing layer 182, thereby measuring distorted information. In addition, transmittance of the transmissive area TA may be reduced by the first light path changing layer 182. Therefore, in the display panel 100 according to one aspect of the present disclosure, the first light path changing layer 182 may not be provided in the plurality of transmissive areas TA.

Meanwhile, the first light path changing layer 182 may be disposed to at least partially overlap the plurality of second subpixels SSP disposed between the plurality of transmissive areas TA. At this time, the first light path changing layer 182 may be provided in at least a portion of the non-light emission area NEA as well as light emission areas EA1, EA2 and EA3 of the second subpixels SSP. For example, the first light path changing layer 182 may be disposed in an area overlapping with a bank 125.

The first light path changing layer 182 may be disposed between light emitting elements of the second subpixels SSP and the first substrate 111. In detail, the first light path changing layer 182 may be provided between the first electrode 120 of the light emitting elements of the second subpixels SSP and a second planarization layer PLN2, but is not limited thereto. The first light path changing layer 182 is disposed on the optical path between the first electrode 120 of the light emitting element of the second subpixels SSP and the first substrate 111, and its position may vary depending on the configuration of the display panel 100. For example, when the second planarization layer PLN2 is omitted from the display panel 100, the first light path changing layer 182 may be disposed between the first electrode 120 and the first planarization layer PLN1 of the second subpixels SSP. For convenience of description, the description will be based on that the first light path changing layer 182 is provided between the first electrode 120 and the second planarization layer PLN2 of the second subpixels SSP.

One surface of the first light path changing layer 182 may be in contact with the first electrode 120 of the second subpixels SSP, and the other surface thereof may be in contact with the second planarization layer PLN2 made of an organic material. The first light path changing layer 182 may be formed of an organic material having a refractive index higher than that of the second planarization layer Pln2.

The light L1 emitted from the organic light emitting layer 130 of the second subpixels SSP may move to the second planarization layer PLN2 by passing through the first light path changing layer 182, and may enter the optical sensor 200 by passing through the first substrate 111. At this time, since the first light path changing layer 182 has a refractive index higher than that of the second planarization layer PLN2, the light L1 is refracted on a boundary surface between the first light path changing layer 182 and the second planarization layer PLN2, whereby an incident angle with respect to the optical sensor 200 may be increased. As a result, as the display panel 100 according to one aspect of the present disclosure includes a first light path changing layer 182, the incident angle of the light L1 emitted from the organic light emitting layer 130 of the second subpixels SSP with respect to the optical sensor 200 may be increased.

The first light path changing layer 182 may include a convex pattern that is convex toward the first substrate 111 from the first electrode 120 of the second subpixels SSP. One or more convex patterns may be provided for each of the second subpixels SSP.

When the plurality of convex patterns are provided, a thickness of the convex pattern may be more reduced than the case that one convex pattern is provided for each of the second subpixels SSP. The convex pattern provided as one for each of the second subpixels SSP may have the same curvature as that of the plurality of convex patterns provided for each of the second subpixels SSP, and may have a larger thickness so as to include the second subpixel SSP. Therefore, a thickness of the display panel 100 may be also increased. The display panel 100 according to one aspect of the present disclosure may include a plurality of convex patterns for each of the second subpixels SSP as shown in FIG. 6, thereby minimizing a thickness increase caused by the first light path changing layer 182.

Meanwhile, the first light path changing layer 182 may have a different curvature for each of the second subpixels SSP. In detail, the first light path changing layer 182 may have a different curvature in each of the first color subpixel SSP1, the second color subpixel SSP2 and the third color subpixel SSP3. In general, intensity of light may be increased as the incident angle is increased. However, intensity of some light may be increased as the incident angle is increased at some period.

In the display panel 100 according to one aspect of the present disclosure, a curvature of the first light path changing layer 182 may vary depending on characteristics of light emitted from each of the first color subpixel SSP1, the second color subpixel SSP2 and the third color subpixel SSP3. The curvature of the first light path changing layer 182 disposed in the first color subpixel SSP1, the second color subpixel SSP2 and the third color subpixel SSP3 may determine an incident angle in which intensity of the light becomes smaller than a reference value, and may be designed based on the determined incident angle.

FIG. 7 is a cross-sectional view illustrating another example of II-II′ of FIG. 3.

The display panel 100 shown in FIG. 7 further includes a second light path changing layer 184 in comparison with the display panel 100 shown in FIG. 6, and the other elements are substantially the same as those described in the display panel 100 shown in FIG. 6. Hereinafter, only the second light path changing layer 184 will be described in detail, and the detailed description of the other elements will be omitted.

The second light path changing layer 184 may be provided between the plurality of second subpixels SSP. In detail, the second light path changing layer 184 may be disposed between the transmissive area TA and the light emitting areas EA1, EA2 and EA3 of the second subpixel SSP. That is, the second light path changing layer 184 may be disposed in the area overlapping with the bank 125.

The second light path changing layer 184 may be disposed to at least partially overlap the bank 125. The second light path changing layer 184 may be disposed between the bank 125 and the second planarization layer PLN2 to change a path of light L3 incident from the second subpixels SSP. At this time, the bank 125 may be provided over the second light path changing layer 184 to cover the second light path changing layer 184.

One surface of the second light path changing layer 184 may be in contact with the bank 125, and may be formed of an organic material having a refractive index higher than that of the bank 125. The second light path changing layer 184 may be formed of the same material as that of the first light path changing layer 182, but is not limited thereto. The second light path changing layer 184 has only to have a refractive index higher than that of the bank 125, and may have a refractive index different from that of the first light path changing layer 182 or may be formed of a material different from that of the first light path changing layer 182.

A portion L3 of the light emitted from the organic light emitting layer 130 of the second subpixels SSP may move to the second light path changing layer 184 by passing through the bank 125. Since the second light path changing layer 184 has a refractive index higher than that of the bank 125, the light L3 may be refracted on a boundary surface between the second light path changing layer 184 and the bank 125 to move toward a second substrate 112. As a result, the display panel 100 according to one aspect of the present disclosure may include a second light path changing layer 184 to induce the light L3, which moves from the organic light emitting layer 130 of the second subpixels SSP to the bank 125, to be emitted upward. Therefore, the display panel 100 according to one aspect of the present disclosure may reduce light moving to a lower portion in the light emitted from the organic light emitting layer 130 of the second subpixels SSP.

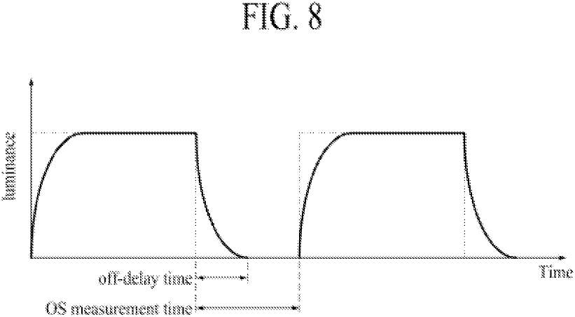

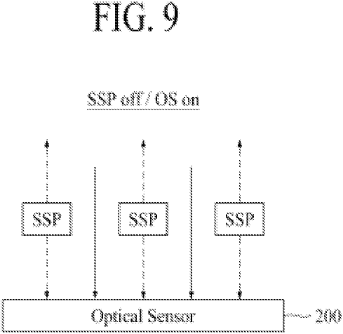

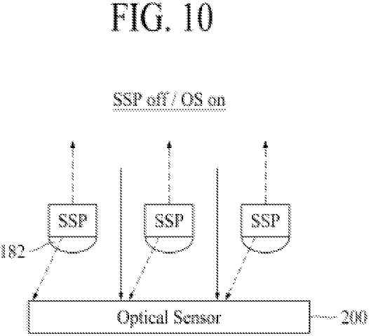

FIG. 8 is a view illustrating an operation relation between an optical sensor and a second subpixel, and FIG. 9 is a view illustrating that interference light due to a second subpixel occurs when an optical sensor operates.

Referring to FIGS. 8 and 9, the second subpixel SSP and the optical sensor 200 do not operate simultaneously. The optical sensor 200 may be turned on/off with a predetermined period. When the optical sensor 200 is turned off, the second subpixel SSP may be switched from an off-state to an on-state in accordance with a control signal. The second subpixel SSP may be in an on-state during the off-state of the optical sensor 200. Therefore, while the optical sensor 200 is not operated, the plurality of second subpixels SSP may emit light to display an image on the second display area DA2.

When the optical sensor 200 is turned on as shown in FIG. 8, the second subpixel SSP may be switched from the on-state to the off-state in accordance with the control signal. The second subpixel SSP may be turned off during the on-state of the optical sensor 200. Therefore, while the optical sensor 200 operates, an image may not be displayed on the second display area DA2. The optical sensor 200 may be turned on, and may measure external light input through the transmissive area TA.

When the second subpixel SSP is switched from the on-state to the off-state, an off-delay time may occur as shown in FIG. 8 in view of material characteristics of the organic light emitting layer 130. Therefore, even though the optical sensor 200 is turned on, the second subpixel SSP may emit predetermined light during the off-delay time. The light emitted from the second subpixel SSP may move to the optical sensor 200 disposed below the display panel 100 as shown in FIG. 9. The optical sensor 200 may interfere with light incident from the second subpixel SSP.

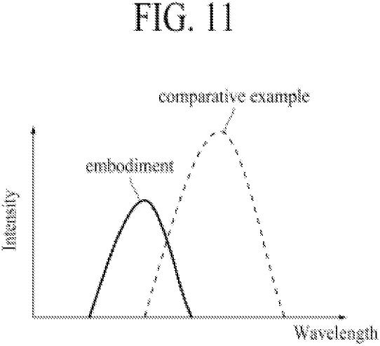

FIG. 10 is a view illustrating that incident light of interference light due to a second subpixel is changed by a first light path changing layer, and FIG. 11 is a graph illustrating intensity of light in a comparative example and an aspect.

Referring to FIGS. 10 and 11, the display panel 110 according to one aspect of the present disclosure may include a first light path changing layer 182 below the second subpixel SSP. A path of light directed from the second subpixel SSP to the optical sensor 200 may be changed by the first light path changing layer 182. In detail, the light directed from the second subpixel SSP to the optical sensor 200 is refracted on the boundary surface of the first light path changing layer 182, whereby an incident angle θ with respect to the optical sensor 200 may be increased. As a result, when an aspect in which the first light path changing layer 182 is provided in the display panel 100 is compared with the comparative example in which the first light path changing layer 182 is not provided in the display panel 100, intensity of light incident on the optical sensor 200 may be reduced as shown in FIG. 11.

According to the present disclosure, the following advantageous effects may be obtained.

In the present disclosure, the first light path changing layer is provided below the subpixel, so that light directed from the subpixel to the optical sensor may be refracted, whereby the incident angle with respect to the optical sensor may be increased. The present disclosure may reduce intensity of the light incident on the optical sensor from the subpixel, and consequently may minimize interference light that affects the optical sensor.

Also, in the present disclosure, the first light path changing layer is disposed only in the non-transmissive area, so that transmittance of the transmissive area may be prevented from being lost, and the external light input to the optical sensor may be prevented from being distorted.

Also, in the present disclosure, the second light path changing layer is provided to overlap the bank, so that light moving from the subpixel to the bank may be induced to be emitted upward. Therefore, the present disclosure may reduce the light moving to the optical sensor among the light emitted from the subpixel.

It will be apparent to those skilled in the art that the present disclosure described above is not limited by the above-described aspects and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate provided with a plurality of transmissive areas;
a plurality of light emitting elements having a first electrode and a light emitting layer disposed between the plurality of transmissive areas; and
a first light path changing layer disposed between the plurality of transmissive areas, changing a path of light directed from the light emitting layer toward the substrate.

2. The display device of claim 1, wherein the first light path changing layer is disposed between the first electrode and the substrate.

3. The display device of claim 2, further comprising:
a plurality of driving transistors connected to the plurality of light emitting elements; and
a planarization layer disposed over the plurality of driving transistors,
wherein the first light path changing layer is disposed between the first electrode and the planarization layer.

4. The display device of claim 3, wherein the first light path changing layer has a refractive index higher than that of the planarization layer.

5. The display device of claim 1, wherein the first light path changing layer includes a convex pattern that is convex toward the substrate from the first electrode.

6. The display device of claim 5, wherein the convex pattern is provided as a plural number for each of the plurality of light emitting elements.

7. The display device of claim 1, further comprising:
a second light path changing layer disposed between the plurality of light emitting elements, changing a path of light incident from the light emitting layer; and
a bank provided between the plurality of light emitting elements to cover the second light path changing layer.

8. The display device of claim 7, wherein the second light path changing layer has a refractive index higher than that of the bank.

9. A display device comprising:
a display panel to display an image; and
an optical sensor disposed below the display panel,
wherein the display panel includes:
a substrate provided with a first display area and a second display area at least partially overlapping with the optical sensor;
a plurality of first subpixels disposed in the first display area;
a plurality of second subpixels disposed in the second display area; and
a first light path changing layer at least partially overlap with each of the second subpixels and changing a path of light directed from the second subpixels toward the substrate.

10. The display device of claim 9, wherein the second display area includes a plurality of transmissive areas and a plurality of non-transmissive areas disposed between the plurality of transmissive areas, and each of the plurality of second subpixels is disposed in each of the plurality of non-transmissive areas.

11. The display device of claim 10, wherein the optical sensor receives external light through the plurality of transmissive areas, and
wherein the second subpixels are turned off so that an image is not displayed on the second display area when an operation of the optical sensor is turned on, and the second subpixels are turned on so that an image is displayed on the second display area when the operation of the optical sensor is turned off.

12. The display device of claim 9, wherein the first light path changing layer is disposed between light emitting elements of the second subpixels and the optical sensor.

13. The display device of claim 9, wherein the first light path changing layer includes a convex pattern that is convex toward the optical sensor from a light emitting element of each of the second sub pixels.

14. The display device of claim 13, wherein the convex pattern is provided as a plural number for each of the second subpixels.

15. The display device of claim 13, wherein the second subpixel includes a first color subpixel emitting a first color light and a second color subpixel emitting a second color light.

16. The display device of claim 15, wherein the convex pattern overlaps with the first color subpixel has a curvature different from that of a convex pattern provided to overlap with the second color subpixel.

17. The display device of claim 9, wherein the first light path changing layer has one surface in contact with a first electrode of a light emitting element of each of the second subpixels, and another surface in contact with a planarization layer made of an organic material, and
wherein the first light path changing layer has a refractive index higher than that of the planarization layer.

18. The display device of claim 9, further comprising:
a second light path changing layer disposed between the transmissive area disposed in the second display area and the second subpixel, changing a path of light incident from the second subpixel; and
a bank provided between the plurality of second subpixels to cover the second light path changing layer.

19. The display device of claim 18, wherein the second light path changing layer has a refractive index higher than that of the bank.

20. The display device of claim 16, wherein the first light path changing layer has a curvature in the first color subpixel and the second color subpixel that determines an incident angle in which intensity of the light becomes smaller than a reference value.
